(19) United States
(12) Patent Application Publication
(10) Pub. No.: US 2016/0181475 A1
(43) Pub. Date: Jun. 23, 2016

(54) SEMICONDUCTOR LIGHT-EMITTING DEVICE

(71) Applicant: PlayNitride Inc., Tainan City (TW)

(72) Inventors: Shen-Jie Wang, Tainan City (TW); Yu-Chu Li, Tainan City (TW)

(21) Appl. No.: 14/941,686

(22) Filed: Nov. 16, 2015

(30) Foreign Application Priority Data
Dec. 23, 2014 (TW) 103144978

(51) Int. Cl. H01L 33/32; H01L 33/12

(52) U.S. Cl. CPC H01L 33/325; H01L 33/12; H01L 2933/0091

(57) ABSTRACT

A semiconductor light-emitting device including a first type doped semiconductor layer, a second type doped semiconductor layer, a light-emitting layer, and a contact layer is provided. The light-emitting layer is disposed between the first type doped semiconductor layer and the second type doped semiconductor layer. The contact layer is disposed on the second type doped semiconductor layer. The second type doped semiconductor layer is disposed between the contact layer and the light-emitting layer. Dopants in the contact layer include a group IVA element and a group IIA element. The group IVA element is an electron donor. The group IIA element is an electron acceptor. The doping concentration of the group IVA element is greater than or equal to 10²⁰ atoms/cm³, and the doping concentration of the group IIA element is greater than or equal to 10²⁰ atoms/cm³.

### CROSS-REFERENCE TO RELATED APPLICATION

This application claims the priority benefit of Taiwan application serial no. 103144978, filed on Dec. 23, 2014. The entirety of the above-mentioned patent application is hereby incorporated by reference herein and made a part of this specification.

### BACKGROUND

1. Field of the Invention

The invention is directed to a light-emitting device and more particularly, to a semiconductor light-emitting device.

2. Description of Related Art

With the evolution of photoelectrical technology, traditional incandescent bulbs and fluorescent lamps have been gradually replaced by solid-state light sources of the new generation, such as light-emitting diodes (LEDs). The LEDs have advantages, such as long lifespans, small sizes, high shock resistance, high light efficiency and low power consumption and thus, have been widely adopted as light sources in applications including household lighting appliances as well as light sources of equipment. Besides being widely adopted in light sources of backlight modules of liquid crystal displays (LCDs) and household lighting appliances, the application of the LEDs have been expanded to street lighting, large outdoor billboards, traffic lights and the related fields in recent years. As a result, the LEDs have been developed as the light sources featuring economic power consumption and environmental protection.

As for a solid-state light source of a semiconductor light-emitting device, a level of its series resistance from a positive electrode to a negative electrode causes affection to the application of the solid-state light source. Generally, in a condition with a constant voltage, as the series resistance is lower, more application changes can be produced.

### SUMMARY

The invention provides a semiconductor light-emitting device capable of reducing series resistance of the semiconductor light-emitting device.

According to an embodiment of the invention, a semiconductor light-emitting device including a first type doped semiconductor layer, a second type doped semiconductor layer, a light-emitting layer and a contact layer is provided. The light-emitting layer is disposed between the first type doped semiconductor layer and the second type doped semiconductor layer. The contact layer is disposed on the second type doped semiconductor layer, and the second type doped semiconductor layer is disposed between the contact layer and the light-emitting layer. Dopants in the contact layer includes a group IVA element and a group IIA element. The group IVA element is an electron donor, and the group IIA element is an electron acceptor. The doping concentration of the group IVA element is greater than or equal to 10²⁰ atoms/cm³, and the doping concentration of the group IIA element is greater than or equal to 10²⁰ atoms/cm³.

In an embodiment of the invention, the contact layer includes a nitride whose dopants includes the group IVA element and the group IIA element.

In an embodiment of the invention, the contact layer comprises a GaN-based compound whose dopants comprise the group IVA element and the group IIA element.

In an embodiment of the invention, the contact layer further comprises at least one of oxygen and carbon.

In an embodiment of the invention, the group IVA element is silicon, and the group IIA element is magnesium.

In an embodiment of the invention, the semiconductor light-emitting device further includes a first electrode and a second electrode. The first electrode is electrically connected to the first type doped semiconductor layer, and the second electrode is disposed on the contact layer.

In an embodiment of the invention, the semiconductor light-emitting device further comprises a transparent conductive layer disposed on the contact layer and located between the second electrode and the contact layer.

In an embodiment of the invention, the first type doped semiconductor layer is an N-type semiconductor layer, and the second type doped semiconductor layer is a P-type semiconductor layer.

In an embodiment of the invention, materials of the first type doped semiconductor layer and the second type doped semiconductor layer comprise gallium nitride (GaN).

In an embodiment of the invention, the contact layer is an ohmic contact layer.

In an embodiment of the invention, a light emitted from the light-emitting layer includes blue light, ultraviolet (UV) light or a combination thereof.

In the semiconductor light-emitting device of the embodiments of the invention, since both the doping concentration of the dopant of the group IVA element serving as the electron donor and the doping concentration of the dopant of the group IIA element serving as the electron acceptor are greater than or equal to 10²⁰ atoms/cm³, the contact layer can have good conductivity and reduce the contact resistance, so as to reduce the overall series resistance of the semiconductor light-emitting device.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional diagram illustrating a semiconductor light-emitting device according to an embodiment of the invention.

FIG. 2 is a cross-sectional diagram illustrating a semiconductor light-emitting device according to another embodiment of the invention.

### DESCRIPTION OF EMBODIMENTS

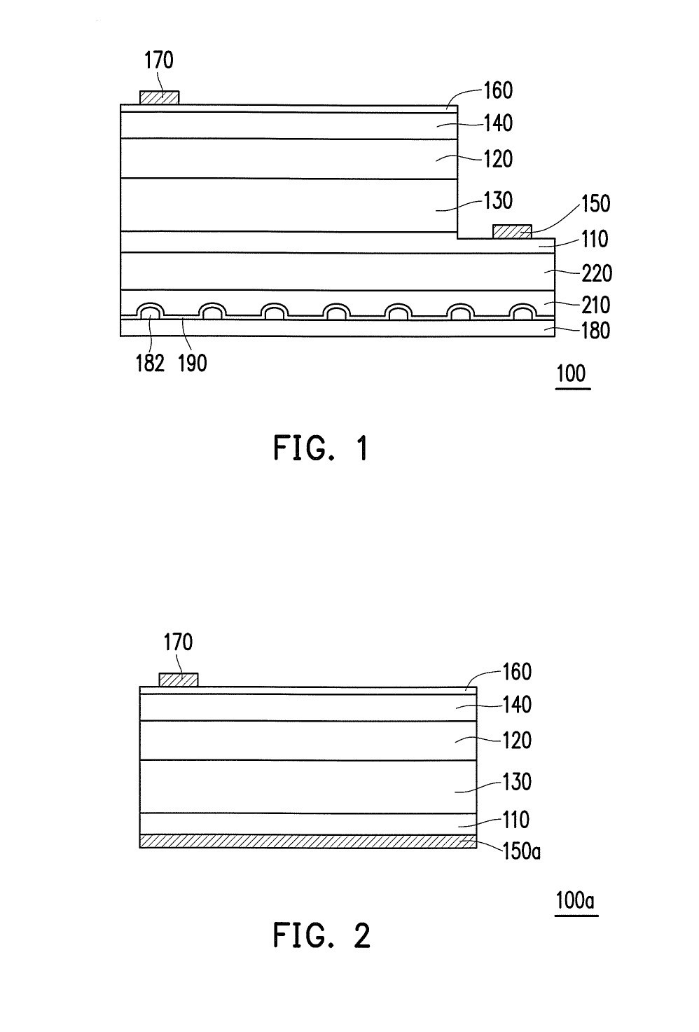

FIG. 1 is a cross-sectional diagram illustrating a semiconductor light-emitting device according to an embodiment of the invention. With reference to FIG. 1, a semiconductor light-emitting device 100 of the present embodiment includes a first type doped semiconductor layer 110, a second type doped semiconductor layer 120, a light-emitting layer 130 and a contact layer 140. The light-emitting layer 130 is disposed between the first type doped semiconductor layer 110 and the second type doped semiconductor layer 120. The contact layer 140 is disposed on the second type doped semiconductor layer 120, and the second type doped semiconductor layer 120 is disposed between the contact layer 140 and the light-emitting layer 130. The light emitted from the light-emitting layer 130 may include blue light, ultraviolet (UV) light or a combination thereof. In the present embodiment, the light-emitting layer 130 is, for example, a multiple quantum well (MQW) layer formed by alternately stacking a plurality of N-type indium gallium nitride (InGaN) layers and a plurality of N-type gallium nitride (GaN) layers, which is capable of emitting the blue light. Additionally, dopants in the contact layer 140 include a group IVA element and a group IIA element. The group IVA element is an electron donor, and the group IIA element is an electron acceptor. The doping concentration of the group IVA element is greater than or equal to 10²⁰ atoms/cm³, and the doping concentration of the group

IIA element is greater than or equal to 10²⁰ atoms/cm³.

In the semiconductor light-emitting device 100 of the present embodiment, both the doping concentration of the dopant of the group IVA element serving as the electron donor and the doping concentration of the dopant of the group IIA element serving as the electron acceptor are greater than or equal to 10²⁰ atoms/cm³, so that the contact layer 140 can have good conductivity and reduce the contact resistance, so as to reduce the overall series resistance of the semiconductor light-emitting device 100.

The contact layer 140 may include a nitride whose dopants include the group IVA element and the group IIA element. In the present embodiment, the contact layer 140 includes a GaN-based compound whose dopants include the group IVA element and the group IIA element, e.g., InGaN. The contact layer 140 may further include at least one of oxygen and carbon. In an embodiment, the contact layer 140 is oxygen-contained InGaN whose dopants include the group IVA element and the group IIA element. Specifically, the group IVA element is, for example, silicon, and the group IIA element is, for example, magnesium.

In the present embodiment, the first type doped semiconductor layer 110 is an N-type semiconductor layer, and the second type doped semiconductor layer 120 is a P-type semiconductor layer. In the present embodiment, materials of the first type doped semiconductor layer 110 and the second type doped semiconductor layer 120 include gallium nitride (GaN), such as GaN having an N-type dopant and GaN having a P-type dopant, respectively.

In the present embodiment, the P-type dopant of the second type doped semiconductor layer 120 is a group IIA element dopant, such as the magnesium dopant. In addition, the N-type dopant of the first type doped semiconductor layer 110 is a group IVA element dopant, such as the silicon dopant.

In the present embodiment, the semiconductor light-emitting device 100 further includes a first electrode 150 and a second electrode 170. The first electrode 150 is electrically connected to the first type doped semiconductor layer 110 and disposed, for example, on the first type doped semiconductor layer 110, and the second electrode 170 is disposed on the contact layer 140. In the present embodiment, the semiconductor light-emitting device 100 further includes a transparent conductive layer 160 (e.g., an indium tin oxide layer) disposed on the contact layer 140, and the second electrode 170 is disposed on the transparent conductive layer 160, namely, the transparent conductive layer 160 is located between the second electrode 170 and the contact layer 140. The contact layer 140 serves to reduce contact resistance between the transparent conductive layer 160 and the second type doped semiconductor layer 120. In the present embodiment, the contact layer 140 is an ohmic contact layer, i.e., has both a high P-type doping concentration and a high N-type doping concentration. Thus, electrical conductivity of the contact layer 140 is similar to the electrical conductivity of a conductor. In this way, the contact layer 140 may be capable of effectively reducing series resistance from the second electrode 170 to the first electrode 150 in the semiconductor light-emitting device 100.

In the present embodiment, the semiconductor light-emitting device 100 further includes a substrate 180, a nucleation layer 190, a buffer layer 210 and an unintentionally doped semiconductor layer 220. In the present embodiment, the substrate 180 is a patterned sapphire substrate having surface patterns 182 (e.g., protruding patterns) to provide a light-scattering effect, so as to improve light extraction efficiency. The nucleation layer 190, the buffer layer 210, the unintentionally doped semiconductor layer 220, the first type doped semiconductor layer 110, the light-emitting layer 130, the second type doped semiconductor layer 120, the contact layer 140, the transparent conductive layer 160 and the second electrode 170 are stacked in sequence on the substrate 180. In the present embodiment, the nucleation layer 190, the buffer layer 210 and the unintentionally doped semiconductor layer 220 are made of, for example, unintentionally doped GaN.

FIG. 2 is a cross-sectional diagram illustrating a semiconductor light-emitting device according to another embodiment of the invention. With reference to FIG. 2, a semiconductor light-emitting device 100a of the present embodiment is similar to the semiconductor light-emitting device 100 of the embodiment illustrated in FIG. 1, but different therefrom in below. The semiconductor light-emitting device 100 of FIG. 1 is a horizontal-type light-emitting diode (LED), in which both the first electrode 150 and the second electrode 170 are located at the same side of the semiconductor light-emitting device 100, while the semiconductor light-emitting device 100a of the present embodiment is a vertical-type LED, in which a first electrode 150a and a second electrode 170 are located at opposite sides of the semiconductor light-emitting device 100. In the present embodiment, the first electrode 150a is an electrode layer disposed on a surface of the first type doped semiconductor layer 110 which is away from the light-emitting layer 130. However, in other embodiments, a conductive substrate may be disposed between the first electrode 150a and the first type doped semiconductor layer 110. Namely, the first electrode 150a and the first type doped semiconductor layer 110 may be respectively disposed on opposite surfaces of the conductive substrate.

To summarize, in the semiconductor light-emitting device of the embodiments of the invention, since both the doping concentration of the dopant of the group IVA element serving as the electron donor and the doping concentration of the dopant of the group IIA element serving as the electron acceptor are greater than or equal to 10²⁰ atoms/cm³, the contact layer can have good conductivity and reduce the contact resistance, so as to reduce the overall series resistance of the semiconductor light-emitting device.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A semiconductor light-emitting device, comprising:
a first type doped semiconductor layer;
a second type doped semiconductor layer;
a light-emitting layer, disposed between the first type doped semiconductor layer and the second type doped semiconductor layer; and
a contact layer, disposed on the second type doped semiconductor layer, wherein the second type doped semiconductor layer is disposed between the contact layer and the light-emitting layer,
wherein dopants in the contact layer comprises a group IVA element and a group IIA element, the group IVA element is an electron donor, the group IIA element is an electron acceptor, the doping concentration of the group IVA element is greater than or equal to 10²⁰ atoms/cm³, and the doping concentration of the group IIA element is greater than or equal to 10²⁰ atoms/cm³.

2. The semiconductor light-emitting device according to claim 1, wherein the contact layer comprises a nitride whose dopants comprise the group IVA element and the group IIA element.

3. The semiconductor light-emitting device according to claim 2, wherein the contact layer comprises a GaN-based compound whose dopants comprise the group IVA element and the group IIA element.

4. The semiconductor light-emitting device according to claim 3, wherein the contact layer further comprises at least one of oxygen and carbon.

5. The semiconductor light-emitting device according to claim 3, wherein the group IVA element is silicon, and the group IIA element is magnesium.

6. The semiconductor light-emitting device according to claim 1, further comprising:
a first electrode, electrically connected to the first type doped semiconductor layer; and
a second electrode, disposed on the contact layer.

7. The semiconductor light-emitting device according to claim 6, further comprising:
a transparent conductive layer, disposed on the contact layer and located between the second electrode and the contact layer.

8. The semiconductor light-emitting device according to claim 1, wherein the first type doped semiconductor layer is an N-type semiconductor layer, and the second type doped semiconductor layer is a P-type semiconductor layer.

9. The semiconductor light-emitting device according to claim 1, wherein materials of the first type doped semiconductor layer and the second type doped semiconductor layer comprise gallium nitride (GaN).

10. The semiconductor light-emitting device according to claim 1, wherein the contact layer is an ohmic contact layer.

11. The semiconductor light-emitting device according to claim 1, wherein a light emitted from the light-emitting layer comprises blue light, ultraviolet (UV) light or a combination thereof.
